(19) United States
(12) Patent Application Publication
(10) Pub. No.: US 2010/0193855 A1
(43) Pub. Date: Aug. 5, 2010

(54) NON-VOLATILE SEMICONDUCTOR MEMORY DEVICE AND METHOD OF MANUFACTURING SAME

(75) Inventor: Kenichiro NAKAGAWA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 12/697,767

(22) Filed: Feb. 1, 2010

(30) Foreign Application Priority Data
Feb. 3, 2009 (JP) 2009-022953

(51) Int. Cl. H01L 29/792; H01L 21/28

(52) U.S. Cl. 257/314; 438/585; 257/E29.309; 257/E21.21

(57) ABSTRACT

A non-volatile semiconductor memory device of small size and high reliability includes a semiconductor substrate; a charge storage film disposed on the semiconductor substrate; a first gate electrode disposed on the charge storage film; a gate insulating film disposed on the semiconductor substrate; a second gate electrode disposed on the gate insulating film; and an inter-gate insulating film disposed between the first gate electrode and the second gate electrode. The length of the first gate electrode is smaller than the length of the second gate electrode. The top surface of the first gate electrode is neither curved nor inclined with respect to the semiconductor substrate.

### REFERENCE TO RELATED APPLICATION

This application is based upon and claims the benefit of the priority of Japanese patent application No. 2009-022953, filed on Feb. 3, 2009, the disclosure of which is incorporated herein in its entirety by reference thereto.

### TECHNICAL FIELD

This invention relates to a non-volatile semiconductor memory device and to a method of manufacturing the device.

### BACKGROUND

A MONOS-type non-volatile semiconductor memory device that uses a nitride (e.g., a silicon nitride film) as a charge storage film is known as one type of non-volatile semiconductor memory. Such a non-volatile semiconductor memory is disclosed in Patent Documents 1 and 2.

In a MONOS-type non-volatile semiconductor memory, a memory gate and a control gate extend in parallel via an insulating layer interposed between these two gates on a channel region between a source region and a drain region. A charge storage film, e.g., an ONO (Oxide-Nitride-Oxide) film obtained by building up an oxide film, a nitride film and an oxide film in the order mentioned, is formed between the memory gate and a semiconductor substrate. The nitride film (e.g., a silicon nitride film) in the ONO film acts as a charge storage film, and the oxide film (e.g., a silicon oxide film) acts as a potential barrier of charge that has been injected into the nitride film.

Next, an example of operation of a MONOS-type non-volatile semiconductor memory will be described.

When information is written to the device, a positive voltage (e.g., 4.5 V) is applied to the source, a positive voltage (e.g., 5.5 V) is applied to the memory gate, a positive voltage lower than that applied to the memory gate is applied to the control gate, and the drain region is grounded. As a result, some of the electrons that flow from the drain region to the source region are accelerated in the channel region underlying the memory gate, and some of these electrons are injected into the ONO film so that information is written to the device.

When information is erased from the device, a positive voltage (e.g., 4.5 V) is applied to the source, a negative voltage (e.g., −0.3 V) is applied to the memory gate, and 0 V or a negative voltage (e.g., 0 to −3 V) is applied to the memory gate. As a result, electron positive-hole pairs ascribable to a band-to-band tunneling are produced within the source region, and some of the positive holes are accelerated by the electric field within the source region and are injected into the ONO film, whereby information is erased.

When information is read out of the device, the source is grounded, a positive voltage (e.g., 2 V) for the memory gate is applied, a positive voltage (e.g., 2 V) for the control gate is applied and a positive voltage (e.g., 1 V) is applied to the drain region. If the state at this time is one in which electrons have been trapped in the ONO film (the write state), the current decreases. In a state in which positive holes have been trapped in the ONO film or a state in which almost no electric charge has been trapped (the erase state), the current increases. Stored information is read out as a result.

[Patent Document 1]

Japanese Patent Kokai Publication No. JP2005-228957A

[Patent Document 2]

Japanese Patent Kokai Publication No. JP2005-260164A

### SUMMARY

The analysis set forth below is given from the standpoint of the present invention.

In the non-volatile semiconductor memory described in Patent Document 1, for example, polysilicon that will become a memory gate is formed as a sidewall on the sidewall of silicon oxide film.

FIGS. 14A-14H illustrate process diagrams for describing a method of forming a memory gate as the sidewall of the silicon oxide film. First, charge storage film precursor layers 52′, 62′ are formed on semiconductor substrates 51, 61, respectively. Next, silicon nitride films 53, 63 are formed in prescribed regions on the charge storage film precursor layers 52′, 62′, respectively [FIGS. 14A, 14E]. Next, memory gate precursor layers 54′, 64′ that will serve as the bases of the memory gates 54, 64, respectively, are formed on regions of the charge storage film precursor layers 52′, 62′ where the silicon nitride films 53, 63 have not been formed [FIGS. 14B, 14F]. Next, the memory gate precursor layers 54′, 64′ are etched back to thereby form memory gates 54, 64, respectively, as sidewalls of the silicon nitride films 53, 63, respectively [FIGS. 14C, 14G]. Next, the memory gate precursor layers 54′, 64′ are etched back to thereby form memory gates 54, 64, respectively, as sidewalls of the silicon nitride films 53, 63, respectively [FIGS. 14C, 14G]. Next, the silicon nitride films 53, 63 are removed and the charge storage film precursor layers 52′, 62′ are etched back to thereby form the memory gates 54, 64 and charge storage films 52, 62, respectively.

In a case where the memory gates 54, 64 are formed as the sidewalls of the silicon nitride films 53, 63, respectively, as illustrated in FIGS. 14A-14H, the shape (length) of the memory gates 54, 64 depends upon the shape of the sidewalls 53a, 63a of the silicon nitride films 53, 63. That is, if the sidewall 53a of the silicon nitride film 53 can be formed perpendicular to the surface of the semiconductor substrate 51, as illustrated in FIGS. 14A-14D, then the sidewall 54a of the memory gate 54 can also be formed perpendicular to the surface of the semiconductor substrate 51. As a result, the length of the charge storage film 52 and the length of the memory gate 54 have the same length L5 and formation can be achieved without causing a mismatch between them. On the other hand, in a case where the sidewall 63a of the silicon nitride film 63 is not formed perpendicular to the surface of the semiconductor substrate 61, as illustrated in FIGS. 14E-14H (e.g., in a case where the sidewall 63a of the silicon nitride film 63 has such a tapered shape that the length of the silicon nitride film 63 extends from the top to the bottom surface, as shown in FIGS. 14A-14H), the sidewall 64a of the memory gate 64 that has been formed on the inclined sidewall 63a takes on such a tapered shape that the length of the memory gate 64 is shortened from the top to the bottom surface of the memory gate 64. In this case, length L6 of the charge storage film 62 and length L7 of the memory gate 64 become mismatched. As a consequence, there is a difference in channel length between the memory gate 54, which has been formed using as a base the side wall 53a of the silicon nitride film 53 perpendicular to the surface of the semiconductor substrate 51, and the memory gate 64, which has been formed on the sidewall 63a of the silicon nitride film 63 that is perpendicular to the surface of the semiconductor substrate 61.

When memory gates having different channel lengths are formed, as illustrated in FIGS. 14D and 14H, erase speed, which is dependent upon channel length, differs from one memory cell to the next. Consequently, in the operation for erasing information in which positive holes are injected into the charge storage film, more positive holes than necessary are injected into the charge storage film having the smaller channel length (memory-gate length). As a result, a deviated charge distribution occurs, the reliability of information storage declines, a load is imposed upon the insulating film and degradation accelerates.

Accordingly, in the method of forming a memory gate as a sidewall of a silicon nitride film in a MONOS-type non-volatile semiconductor memory device, the reliability of the non-volatile semiconductor memory device declines if there is a variation in the shape of the layer (the silicon nitride film in FIGS. 14A-14H) serving as the foundation.

Further, in a method of forming whichever of the memory gate and control has the smaller length (the memory gate, for example) as the sidewall, problems arise in terms of enhancing the performance and reducing the size of the non-volatile semiconductor memory device.

In a case where the memory gate and control gate are formed of polysilicon, the resistance values of the memory gate and control gate rise. In a MONOS-type non-volatile semiconductor memory, therefore, usually metal wiring (backing wiring) that extends in parallel with the memory gate and control gate is formed and the memory gate and control gate are electrically connected (termed as “backing”) to the metal wiring by contacts, thereby lowering the resistance of the memory gate and control gate. Although the number of contacts depends upon whether or not the memory gate and control gate are silicided, backing is required even in a case where the memory gate and control gate are silicided.

On the other hand, in order to connect the memory gate and the control gate with contacts, it is required that the connection locations have a prescribed area. However, with a method in which a first gate electrode of large length is formed using lithography and a second gate electrode of small length is formed as a sidewall, as in the non-volatile semiconductor memory device illustrated in FIG. 1 of Patent Document 2, the length of the second gate electrode becomes fixed and it is not possible to partially extend only a prescribed region. Therefore, even in a case where it is desired to shorten the length of the second gate electrode in order to improve the performance of the semiconductor memory device, the second gate electrode must be made greater than a certain length in order to assure enough area to electrically connect the second gate electrode with the contact, and a problem which arises in this case is an increase in the number of process steps. If the length of the second gate electrode is enlarged, however, the performance of the non-volatile semiconductor memory device declines and the size of the device increases.

Furthermore, in order to reduce the size of the non-volatile semiconductor memory device, it is required that the top surfaces of the memory gate and control gate be silicided. If the top surfaces of the memory gate and control gate are not silicided, it is necessary that the number of locations (backing locations) where electrical connections are made to the back-stamp wiring be made greater in comparison with a case where the silicidation is carried out. Since a prescribed area for making the electrical connection with the contacts is required for the sake of backing, as mentioned above, a reduction in the size of the non-volatile semiconductor memory device cannot be achieved if the number of backing locations is enlarged. On the other hand, in a case where the top surfaces of the memory gate and control gate are silicided, it is necessary to prevent short-circuiting of the memory gate and control gate. Thus there is much desired in the art.

In accordance with a first aspect of the present invention, there is provided a non-volatile semiconductor memory device which comprises: a semiconductor substrate; a charge storage (or accumulation) film disposed on the semiconductor substrate; a first gate electrode disposed on the charge storage film; a gate insulating film disposed on the semiconductor substrate; a second gate electrode disposed on the gate insulating film; and an inter-gate insulating film disposed between the first gate electrode and the second gate electrode. The length of the first gate electrode is smaller than that of the second gate electrode. The top surface of the first gate electrode is neither curved nor inclined with respect to the semiconductor substrate.

In accordance with a second aspect of the present invention, there is provided a method of manufacturing a non-volatile semiconductor memory device, which comprises: forming a first gate electrode, which has been formed utilizing lithography, on a semiconductor substrate; and forming a second gate electrode, which has a length greater than that of the first gate electrode, as a sidewall of at least the first gate electrode.

The meritorious effects of the present invention are summarized as follows.

The present invention has at least one of the following effects:

In accordance with the present invention, whichever of the first gate electrode and second gate electrode has the smaller length is not formed as a sidewall. As a result, a variation in performance, which is due to a variation in the length of the first gate electrode, and degradation of insulating film can be reduced. This makes it possible to enhance the reliability of the non-volatile semiconductor memory device.

In accordance with the present invention, whichever of the first gate electrode and second gate electrode has the smaller length can be formed using lithography. As a result, only the prescribed region can be extended and sufficient area for “backing” acquired while gate length is reduced.

### BRIEF DESCRIPTION OF THE DRAWINGS

FIG. 1 is a schematic plan view of a non-volatile semiconductor memory device according to a first exemplary embodiment of the present invention;

FIG. 2 is a schematic sectional view of FIG. 1 taken along line

FIG. 3 is a schematic sectional view of FIG. 1 taken along line III-III;

FIGS. 4A to 4E are schematic process views for describing a method of manufacturing a non-volatile semiconductor memory device according to a first exemplary embodiment of the present invention;

FIGS. 5A to 5D are schematic process views for describing a method of manufacturing a non-volatile semiconductor memory device according to a first exemplary embodiment of the present invention;

FIGS. 6A to 6D is a schematic process view for describing a method of manufacturing a non-volatile semiconductor memory device according to a first exemplary embodiment of the present invention;

FIGS. 7A to 7E is a schematic process view for describing a method of manufacturing a non-volatile semiconductor memory device according to a first exemplary embodiment of the present invention;

FIG. 8 is a schematic plan view of a non-volatile semiconductor memory device according to a second exemplary embodiment of the present invention;

FIG. 9 is a schematic sectional view of FIG. 8 taken along line IX-IX;

FIG. 10 is a schematic plan view illustrating a semiconductor substrate of a non-volatile semiconductor memory device according to a second exemplary embodiment of the present invention;

FIGS. 11A to 11D are schematic process views for describing a method of manufacturing a non-volatile semiconductor memory device according to a second exemplary embodiment of the present invention;

FIGS. 12A to 12D are schematic process views for describing a method of manufacturing a non-volatile semiconductor memory device according to a second exemplary embodiment of the present invention;

FIGS. 13A to 13E are schematic process views for describing a method of manufacturing a non-volatile semiconductor memory device according to a second exemplary embodiment of the present invention;

FIGS. 14A to 14H are schematic sectional views illustrating a memory gate portion for describing a problem to be solved by the present invention; and

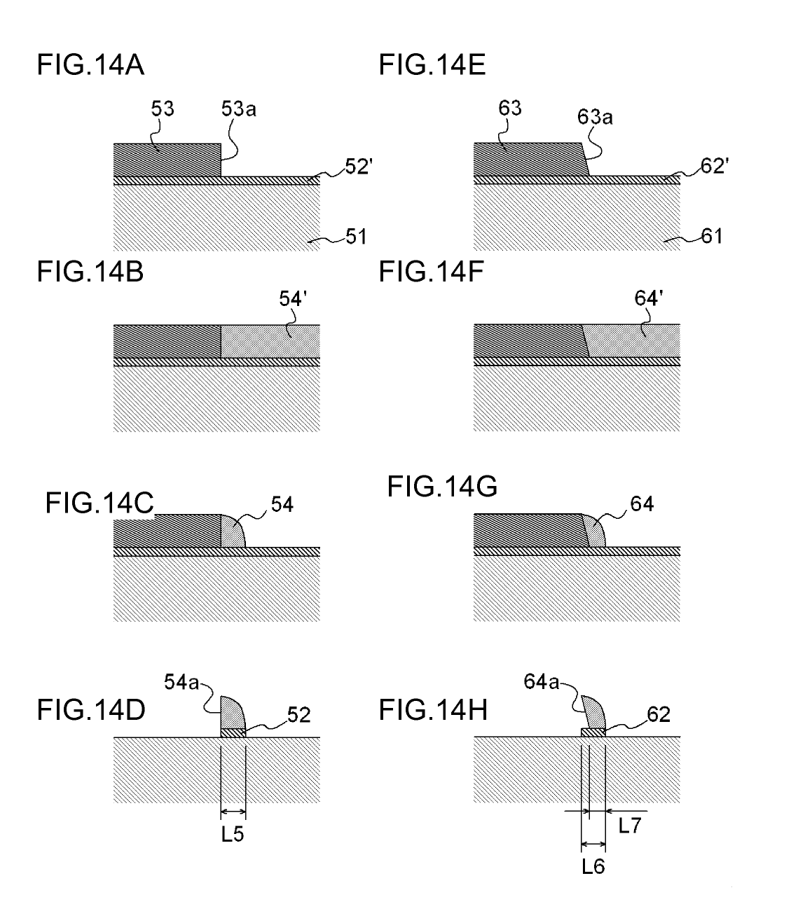

FIG. 15 is a schematic plan view illustrating a semiconductor substrate of a non-volatile semiconductor memory device in which diffusion-region wiring is not formed.

### PREFERRED MODES

Preferred modes of the first and second aspects are described below.

In accordance with a preferred mode of the first aspect, height of the uppermost end of the first gate electrode with respect to the surface of the semiconductor substrate and height of the uppermost end of the second gate electrode with respect to the surface of the semiconductor substrate are different.

In accordance with a preferred mode of the first aspect, height of the uppermost end of the first gate electrode with respect to the surface of the semiconductor substrate is lower than height of the uppermost end of the second gate electrode with respect to the surface of the semiconductor substrate.

In accordance with a preferred mode of the first aspect, the first gate electrode and the second gate electrode each have polysilicon and each has a silicide film on the top surface thereof. The inter-gate insulating film is disposed on a side surface facing whichever of the first and second gate electrodes is the higher gate electrode, which opposes the other gate electrode that is the lower gate electrode, the inter-gate insulating film extending between the top surface of the one gate electrode and the top surface of the other gate electrode.

In accordance with a preferred mode of the first aspect, the inter-gate insulating film has a lower inter-gate insulating film extending from the surface of the semiconductor substrate to the top surface of the one gate electrode, and an upper inter-gate insulating film extending from the top surface of the one gate electrode to the top surface of the other gate electrode.

In accordance with a preferred mode of the first aspect, the composition of the gate insulating film and the composition of the lower inter-gate insulating film are different.

In accordance with a preferred mode of the first aspect, the composition of the charge storage film and the composition of the lower inter-gate insulating film are different.

In accordance with a preferred mode of the first aspect, the non-volatile semiconductor memory device further comprises diffusion-region wiring disposed on a first impurity diffusion region of the semiconductor substrate; and an inter-gate wiring insulating film disposed between the diffusion-region wiring and the first gate electrode. The charge storage film and the first gate electrode are disposed on both sides of the diffusion-region wiring. The gate insulating film and the second gate electrode are disposed on the side of each charge storage film and each first gate electrode that is opposite the diffusion-region wiring. A second impurity diffusion region of the semiconductor substrate is disposed on the side of each gate insulating film and each second gate electrode that is opposite the charge storage film and the first gate electrode.

In accordance with a preferred mode of the first aspect, the height of the uppermost end of the first gate electrode with respect to the surface of the semiconductor substrate and height of the uppermost end of the diffusion-region wiring with respect to the surface of the semiconductor substrate are different.

In accordance with a preferred mode of the first aspect, the height of the uppermost end of the first gate electrode with respect to the surface of the semiconductor substrate is lower than height of the uppermost end of the diffusion-region wiring with respect to the surface of the semiconductor substrate.

In accordance with a preferred mode of the first aspect, the diffusion-region wiring comprises polysilicon and has a silicide film on a top surface thereof. The inter-gate wiring insulating film is disposed on a side surface facing whichever of the first gate electrode and diffusion-region wiring is the higher one, which opposes the one that is the lower, the inter-gate wiring insulating film extending between the top surface of the one and the top surface of the other.

In accordance with a preferred mode of the first aspect, the inter-gate wiring insulating film has a lower inter-gate wiring insulating film extending from the surface of the semiconductor substrate to the top surface of the one, and an upper inter-gate wiring insulating film extending from the top surface of the one to the top surface of the other.

In accordance with a preferred mode of the first aspect, the composition of the charge storage film and the composition of the lower inter-gate wiring insulating film are different.

In accordance with a preferred mode of the first aspect, the top surface of the first gate electrode is a planar shape parallel to the surface of the semiconductor substrate.

In accordance with a preferred mode of the first aspect, the first gate electrode is formed using lithography.

In accordance with a preferred mode of the first aspect, the top surface of the second gate electrode is a curved surface or is inclined with respect to the surface of the semiconductor substrate.

In accordance with a preferred mode of the first aspect, the second gate electrode is formed as a sidewall utilizing at least the first gate electrode.

In accordance with a preferred mode of the first aspect, the first gate electrode is a memory gate, and the second gate electrode is a control gate.

In accordance with a preferred mode of the second aspect, the first electrode formed utilizing lithography is formed on the semiconductor substrate, and the second gate electrode, which has a length greater than that of the first electrode, is formed as the sidewall of at least the first gate electrode.

In accordance with a preferred mode of the second aspect, the method further includes: forming a charge storage film on the semiconductor substrate; forming the first electrode on the charge storage film; forming a laminate, which has the charge storage film and the first gate electrode, into a prescribed shape using lithography; forming an inter-gate insulating film on at least one side surface of the laminate; forming a gate insulating film on the semiconductor substrate; and forming the second gate electrode on the gate insulating film as a sidewall of the laminate via the inter-gate insulating film.

In accordance with a preferred mode of the second aspect, the method further includes: forming the second electrode after a lift-up film is formed on the first electrode in order to make the height of the second gate electrode greater than that of the first gate electrode; and removing the lift-up film after the second electrode is formed.

In accordance with a preferred mode of the second aspect, the method further includes forming an inter-gate insulating film, after the lift-up film is removed, at least at a portion between a top surface of the first gate electrode and a top surface of the second gate electrode along a side surface of the second gate electrode opposing the first gate electrode.

In accordance with a preferred mode of the second aspect, the first and second gate electrodes comprise polysilicon, and least a portion of the top surface of each of the first and second gate electrodes is silicided.

In accordance with a preferred mode of the second aspect, the method further includes: forming two of the first gate electrodes spaced a prescribed distance apart on the semiconductor substrate; forming an inter-gate insulating film along a side surface of one of the gate electrode or the laminate and forming an inter-gate wiring insulating film along a side surface of the other; and forming diffusion-region wiring on a first impurity diffusion region of the semiconductor substrate between the two first gate electrodes as a sidewall of at least the first gate electrode via the inter-gate wiring insulating film; wherein the second gate electrode is formed, via the inter-gate insulating film, on the side of each first gate electrode that is opposite the diffusion-region wiring.

In accordance with a preferred mode of the second aspect, the diffusion-region wiring is formed together with the second gate electrode.

In accordance with a preferred mode of the second aspect, the second gate electrode and the diffusion-region wiring are formed by forming a gate insulating film precursor layer that will serve as the base of the gate insulating film; forming a first second gate electrode precursor layer that will serve as the base of the second gate electrode and diffusion-region wiring; removing the first second gate electrode precursor layer on the region that forms the first impurity diffusion region; forming the first impurity diffusion region by injecting an impurity into the semiconductor substrate; and forming a second second gate electrode precursor layer that will serve as the base of the second gate electrode and diffusion-region wiring.

In accordance with a preferred mode of the second aspect, the method further includes: forming the second electrode and the diffusion region after a lift-up film is formed on the first electrode in order to make the height of the second gate electrode and diffusion-region wiring greater than that of the first gate electrode; and removing the lift-up film after the second electrode and diffusion-region wiring are removed.

In accordance with a preferred mode of the second aspect, the method further includes forming an inter-gate insulating film, after the lift-up film is removed, at least at a portion between the top surface of the first gate electrode and the top surface of the second gate electrode along a side surface of the second gate electrode opposing the first gate electrode; and forming an inter-gate insulating film at least at a portion between the top surface of the first gate electrode and the top surface of the diffusion-region wiring along a side surface of the diffusion-region wiring opposing the first gate electrode.

In accordance with a preferred mode of the second aspect, the diffusion-region wiring comprises polysilicon, and at least a portion of the top surface of the diffusion-region wiring is silicided.

In accordance with a preferred mode of the second aspect, a region connecting a contact to the first gate electrode is formed together with the first gate electrode using lithography.

### Examples

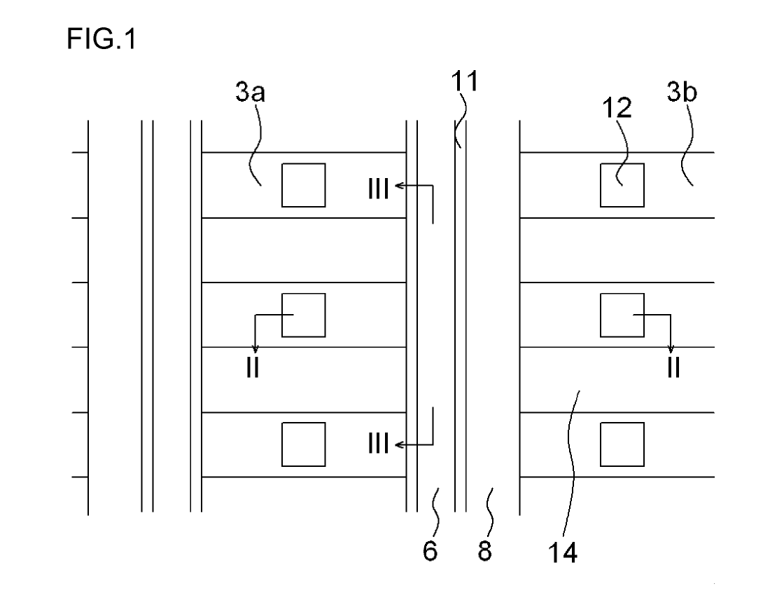

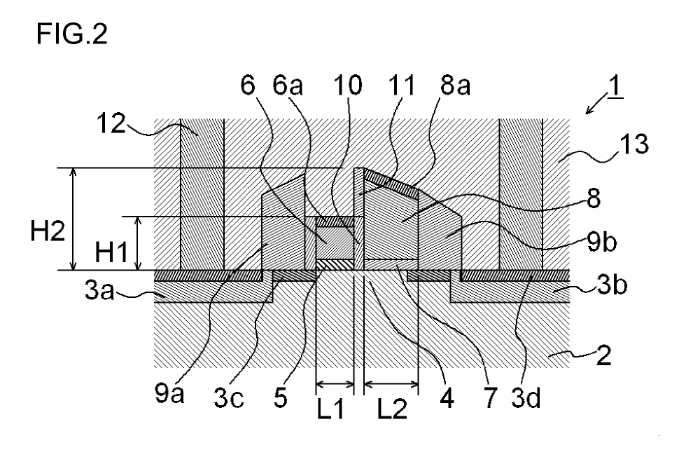

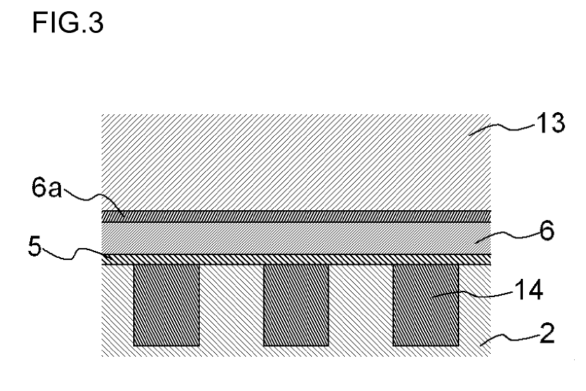

A non-volatile semiconductor memory device according to a first exemplary embodiment of the present invention will now be described. FIG. 1 is a schematic plan view of a non-volatile semiconductor memory device according to a first exemplary embodiment of the present invention; FIG. 2 is a schematic sectional view of FIG. 1 taken along line II-II; and FIG. 3 is a schematic sectional view of FIG. 1 taken along line III-III. It should be noted that an interlayer insulating film 13, protective insulating films 9a, 9b and silicide films 3d, 6a, 8a are not illustrated in FIG. 1.

A non-volatile semiconductor memory device 1 comprises: a semiconductor substrate 2; a charge storage film 5 disposed on the semiconductor substrate; a memory gate 6 serving as a first gate electrode formed on the charge storage film 5; a gate insulating film 7 formed adjacent to the charge storage film 5; and a control gate 8 serving as a second gate electrode formed on the gate insulating film 7.

A first impurity diffusion region (e.g., a source region) 3a and a second impurity diffusion region (e.g., a drain region) 3b [inclusive of an LDD (Lightly Doped Drain) 3c] are formed in the semiconductor substrate 2 (e.g., a silicon substrate), and a channel region 4 is formed between the first impurity diffusion region 3a and the second impurity diffusion region 3b. The first impurity diffusion region 3a, second impurity diffusion region 3b and channel region 4 are isolated from a first impurity diffusion region 3a, second impurity diffusion region 3b and channel region 4 by element isolation regions 14. A third silicide film 3d is formed on the surface of the first impurity diffusion region 3a and second impurity diffusion region 3b, and the first impurity diffusion region 3a and second impurity diffusion region 3b are electrically connected via an overlying wiring layer (not shown) and contacts 12.

The charge storage film 5 extends along the channel region 4. An ONO (Oxide-Nitride-Oxide) film obtained by building up, e.g., a silicon oxide film, a silicon nitride film and a silicon oxide film in the order mentioned, can be used as the charge storage film 5.

The memory gate 6 extends along the charge storage film 5. The memory gate 6 can be formed of polysilicon, by way of example. A first silicide layer 6a is formed on the top surface of the memory gate 6. Preferably, the memory gate 6 is formed using lithography and is not formed as a sidewall of the control gate 8. In this case, the top surface of the memory gate 6 preferably is not a curved shape or is not inclined with respect to the semiconductor substrate 2. Further, it is preferred that the top surface of the memory gate 6 be flat, and it is particularly preferred that the top surface be parallel to the semiconductor substrate 2. By forming the memory gate 6 using a lithographic process, a variation in the dimensions of a plurality of the memory gates 6 can be reduced. Further, only the portion electrically connected to the contact can be partially extended while the memory gate 6 is formed to have a prescribed length.

The gate insulating film 7 also extends along the channel region 4 adjacent to the charge storage film 5. A silicon oxide film, for example, can be used as the gate insulating film 7.

The control gate 8, which serves also as a word line, extends on the gate insulating film 7. The control gate 8 can be formed of polysilicon, by way of example. A second silicide film 8a is formed on the top surface of the control gate 8. Preferably, the control gate 8 is formed as the sidewall of at least the memory gate 6. In this case, the top surface has a curved shape or is a surface that is inclined with respect to the semiconductor substrate 2.

The plurality of charge storage films 5, gate insulating films 7, memory gates 6 and control gates 8 extend in parallel in one direction. A plurality of bit lines (not shown) extend in parallel in one direction above these so as to run at right angles to the control gates 8.

In this exemplary embodiment, length L1 of the memory gate 6 is smaller than length L2 of the control gate 8. Preferably, the length L1 of the memory gate 6 is such that there will be no influence upon erasure of information, and the length L2 of the control gate 8 is set such that writing error will not occur. Further, height H1 of the memory gate 6 (namely the height of the side surface opposing the control gate 8) and height H2 of the control gate 8 (namely the height of the side surface opposing the memory gate 6) are different from each other. For example, the height H1 of the uppermost end of the side surface of memory gate 6 opposing the control gate 8 can be made 50 nm or more lower than the height H2 of the uppermost end of the side surface of the control gate 8 opposing the memory gate 6. It should be noted that in the present invention, the lengths of the gate electrodes (memory gate 6 and control gate 8) refer to lengths that are the same as the gate lengths and are in a direction transverse to the cross section shown in FIG. 2.

In this exemplary embodiment, the length of the memory gate 6 is made smaller than the length of the control gate 8. However, the present invention is applicable also in a case where the first gate electrode is the control gate, the second gate electrode is the memory gate and the length of the memory gate is made greater than the length of the control gate.

Inter-gate insulating films 10, 11 for preventing electrical contact between the memory gate 6 and control gate 8 are formed between the memory gate 6 and control gate 8. The lower inter-gate insulating film 10 extends from the surface of the semiconductor substrate 2 to the top surface of the memory gate 6 along the side surface of the control gate 8 opposing the memory gate 6. The upper inter-gate insulating film 11 extends from the top surface of the memory gate 6 to the top surface of the control gate 8 along the side surface of the control gate 8 opposing the memory gate 6. A short circuit between the first silicide layer 6a and second silicide film 8a can be prevented by the upper inter-gate insulating film 11.

Further, in this exemplary embodiment, the lower inter-gate insulating film 10 extends also along the side surface of the charge storage film 5 and the side surface of the memory gate 6 that are on the side opposite the control gate 8.

The composition of the gate insulating film 7 and the composition of the lower inter-gate insulating film 10 can be made different from each other, the composition of the charge storage film 5 and the composition of the lower inter-gate insulating film 10 can be made different from each other, and the composition of the inter-gate insulating film 10 and the composition of the upper inter-gate insulating film 11 can be made different from each other. For example, silicon oxide film can be used as the gate insulating film 7, ONO film can be used as the charge storage film 5, ON (Oxide-Nitride) film can be used as the lower inter-gate insulating film 10, and silicon oxide film can be used at the upper inter-gate insulating film 11.

In this exemplary embodiment, first protective insulating film 9a is formed on the side of memory gate 6 that is opposite control gate 8, and second protective insulating film 9b is formed on the side of control gate 8 that is opposite memory gate 6. The side surface of the second protective insulating film 9b, which is on the side of the control gate 8, opposing the control gate 8 has a height equivalent to that of the side surface of the opposing control gate 8, but the height of the first protective insulating film 9a on the side of memory gate 6 is greater than that of the memory gate 6.

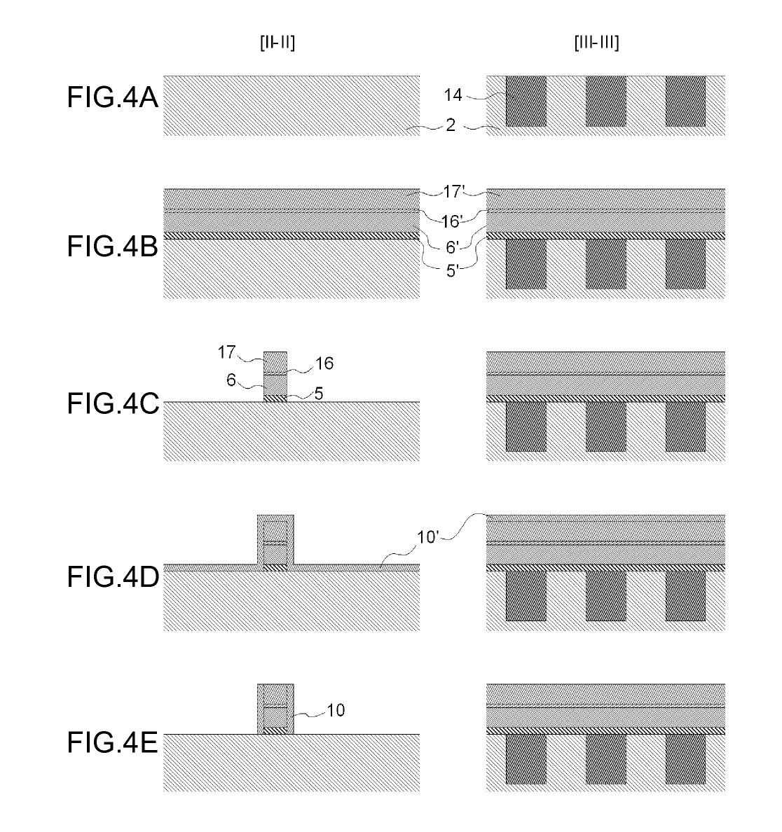

Next, a method of manufacturing the non-volatile semiconductor memory device according to the first exemplary embodiment of the present invention will be described. FIGS. 4A to 7E are schematic process views for describing a method of manufacturing the non-volatile semiconductor memory device according to the first exemplary embodiment of the present invention shown in FIGS. 1 to 3. It should be noted that in each of FIGS. 4A to 7E, the left side illustrates a schematic sectional view of a portion corresponding to the sectional portion of FIG. 1 taken along line II-II, and the right side illustrates a schematic sectional view of a portion corresponding to the sectional portion of FIG. 1 taken along line III-III.

First, the element isolation region 14 is formed in a prescribed region of the semiconductor substrate (e.g., a silicon substrate) 2 [FIG. 4A]. Next, a charge storage film precursor layer (e.g., an ONO layer) 5′ that will serve as the base of the charge storage film 5, a memory gate precursor layer (e.g., a polysilicon layer) 6′ that will serve as the base of the memory gate 6, a third protective film precursor layer 16′ that will serve as the base of a third protective insulating film (e.g., a silicon oxide film) 16 and a lift-up film precursor layer 17′ that will serve as the base of a lift-up film (a silicon oxide film) are built up on the semiconductor substrate 2 in the order mentioned [FIG. 4B]. The lift-up film 17 is a film for making the height of the control gate 8 greater than that of the memory gate 6 when the control gate 8 is formed as a sidewall at a subsequent step, and the film thickness thereof is set appropriately in accordance with the height of the control gate 8. Preferably, the lift-up film 17 and the third protective insulating film 16 are made of different materials so as to allow selective etching. Next, a resist is patterned (not shown) on the lift-up film precursor layer 17′ using a lithographic process, the laminate consisting of the charge storage film precursor layer 5′, memory gate precursor layer 6′, third protective film precursor layer 16′ and lift-up film precursor layer 17′ is patterned into a prescribed shape using the resist as a mask, and the resist is then removed [FIG. 4C]. Next, a lower inter-gate insulating film precursor layer (e.g., an ON layer) 10′ that will serve as the base of the lower inter-gate insulating film 10 is formed [FIG. 4D] and the lower inter-gate insulating film 10 is formed as the sidewall of the laminate by etching [FIG. 4E]. By including a nitride film in the lower inter-gate insulating film 10, the effect upon the oxide film by subsequent steps can be alleviated.

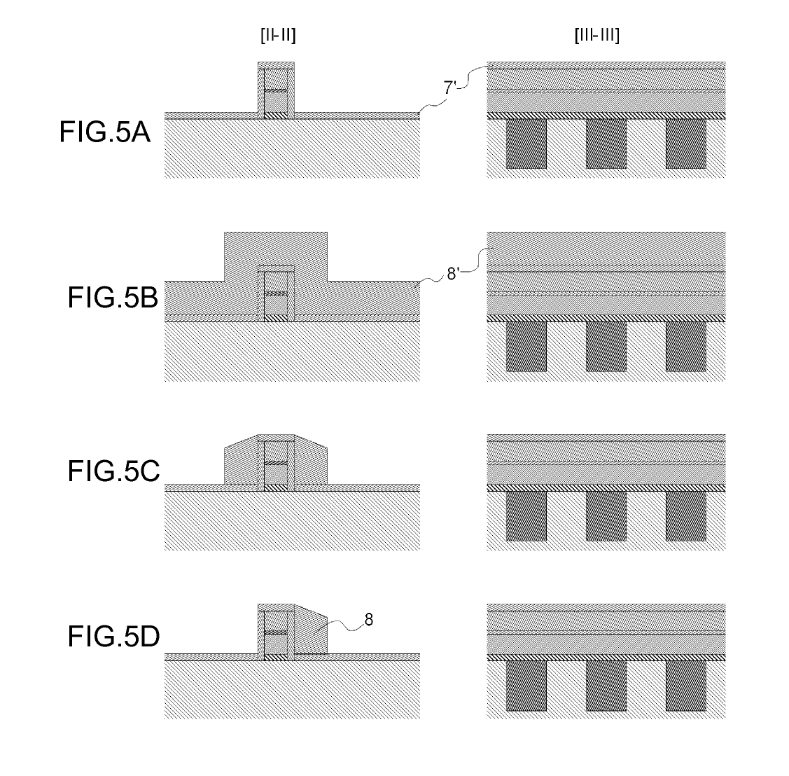

Next, a gate insulating film precursor layer 7′ (e.g., a silicon oxide film) 7′ that will serve as the base of the gate insulating film 7 is formed by oxidation [FIG. 5A]. Next, a control gate precursor layer 8′ (e.g., a polysilicon layer) 8′ that will serve as the base of the control gate 8 is formed [FIG. 5B]. Next, the control gate precursor layer 8′ is etched back to form sidewalls on both sides of the laminate [FIG. 5C], and the sidewall on one side of the laminate is removed using a resist mask, thereby forming the control gate 8 [FIG. 5D].

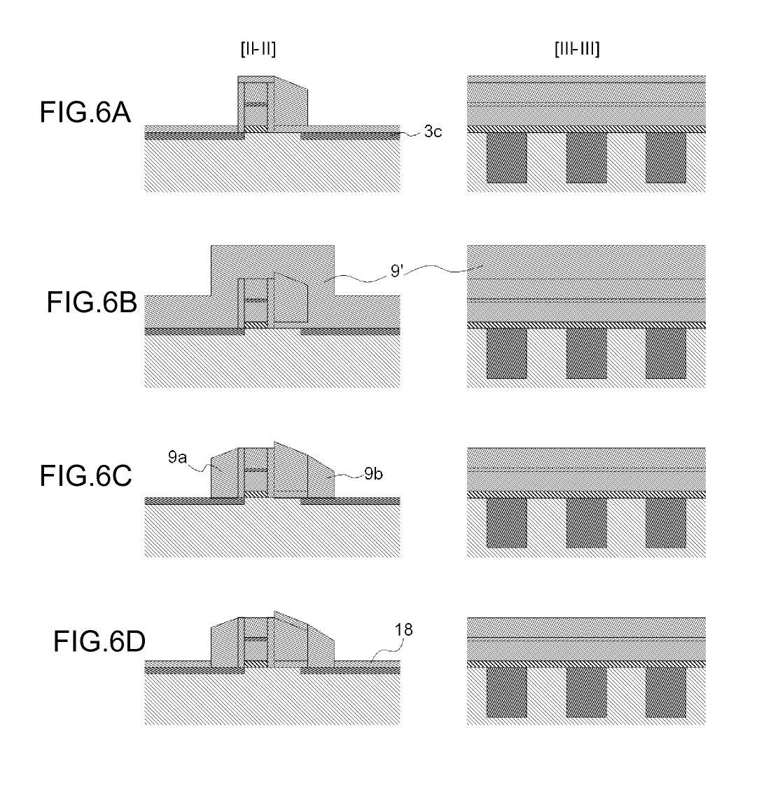

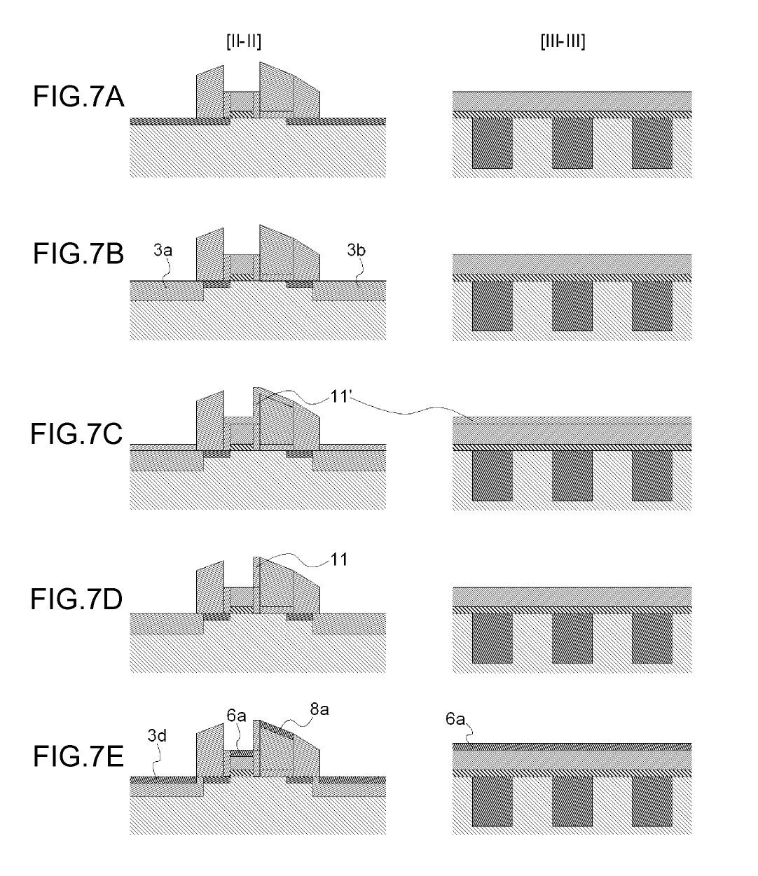

Next, the LDDc 3c is formed by injecting an impurity (e.g., As) into the semiconductor substrate 2 [FIG. 6A]. Next, first and second protective insulating film precursor layers (e.g., silicon oxide film) 9′ that will serve as the bases of the first and second protective insulating films 9a, 9b are grown [FIG. 6B] and then etched back [FIG. 6C]. Next, in a case where the lift-up film 17 is a silicon nitride film and the third protective insulating film 16 is a silicon oxide film, by way of example, the entirety is oxidized under conditions in which the lift-up film 17 is not oxidized, thereby forming a fourth protective insulating film (e.g., a silicon oxide film) 18 [FIG. 6D]. Next, the lift-up film 17 on the memory gate 6 is removed using the fourth protective insulating film 18 as a mask, then the third protective insulating film 16 and fourth protective insulating film 18 are removed [FIG. 7A].

Next, an impurity (e.g., N⁺) is injected into the semiconductor substrate 2 to thereby form the first and second impurity diffusion regions 3a, 3b that will become the source region and drain region [FIG. 7B]. Next, an upper inter-gate insulating film precursor layer (e.g., a silicon oxide film) 11′ that will serve as the base of the upper inter-gate insulating film 11 is formed [FIG. 7C], and the upper inter-gate insulating film 11 is formed by etch-back [FIG. 7D]. Next, the top surfaces of the memory gate 6, control gate 8 and first and second first impurity diffusion regions 3a, 3b are silicided to thereby form the silicide films 6a, 8a, 3d [FIG. 7E]. Next, the interlayer insulating film 13, contact 12 and wiring, etc., are formed (not shown) in the order mentioned, thereby manufacturing the non-volatile semiconductor memory device 1.

In the above-described method of manufacture, the memory gate 6 is formed using a lithographic process and the control gate 8 is formed as a sidewall. However, the control gate 8 can be formed using the lithographic process and the memory gate 6 can be formed as a sidewall. At such time it is preferred that the gate having the smaller of the lengths (L1, L2 shown in FIG. 2) be formed using the lithographic process. By using lithography, even though the gate is the gate having the smaller length, only the prescribed location that forms the backing contact for lowering electrical resistance is partially extended so that enough area for connection to the contact can be assured. Further, if the memory gate 6 is formed using lithography, a variation in length can be reduced. As a result, damage to the insulating film and a deviation in the charge distribution can be suppressed and it is possible to enhance the reliability of the non-volatile semiconductor memory device. Furthermore, in accordance with the above-described method of manufacture, the height of the memory gate 6 and the height of the control gate 8 are changed and the upper and lower inter-gate insulating films 10, 11 are disposed between these two gates, thereby making it possible to prevent a short circuit between the memory gate 6 (inclusive of the silicide film 6a) and the control gate 8 (inclusive of the silicide film 8a).

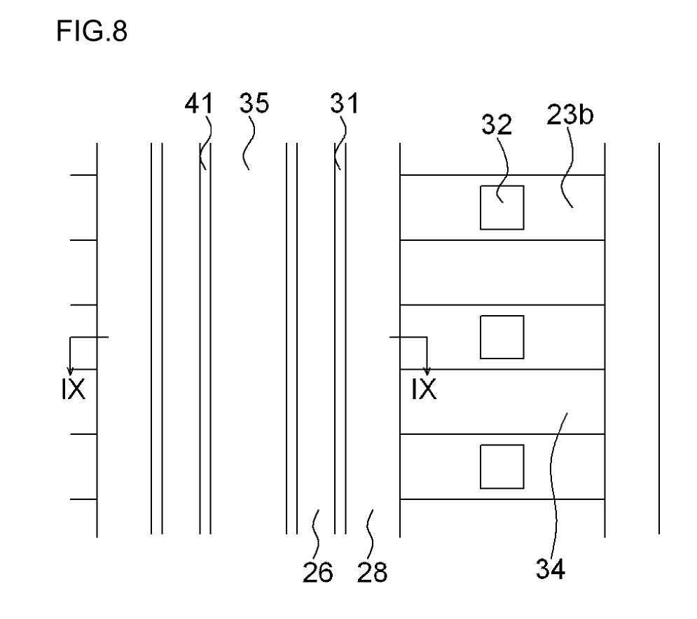

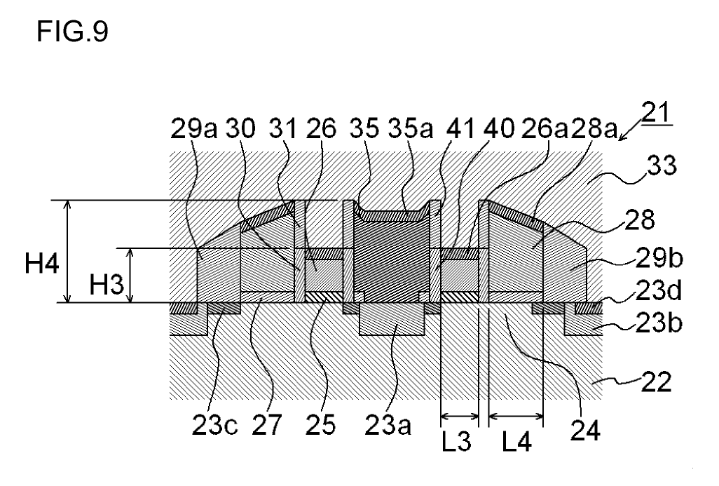

Next, a non-volatile semiconductor memory device according to a second exemplary embodiment of the present invention will now be described. FIG. 8 is a schematic plan view of a non-volatile semiconductor memory device according to a second exemplary embodiment of the present invention, and FIG. 9 is a schematic sectional view of FIG. 8 taken along line IX-IX. It should be noted that an interlayer insulating film 33, protective insulating films 29a, 29b and silicide films 23d, 26a, 28a, 35a are not illustrated in FIG. 8.

In this exemplary embodiment, diffusion-region wiring 35 is formed on a first impurity diffusion region 23a, and memory cells are formed on both sides of the diffusion-region wiring 35. Memory gates 26 are disposed on both sides of the diffusion-region wiring 35. Control gates 28 are disposed on respective sides of the memory gates 26 that are opposite the diffusion-region wiring 35. Second impurity diffusion regions 23b are formed on the control gates 28 on respective sides that are opposite memory gates 26. The diffusion-region wiring 35 extends along the memory gates 26 and control gates 28.

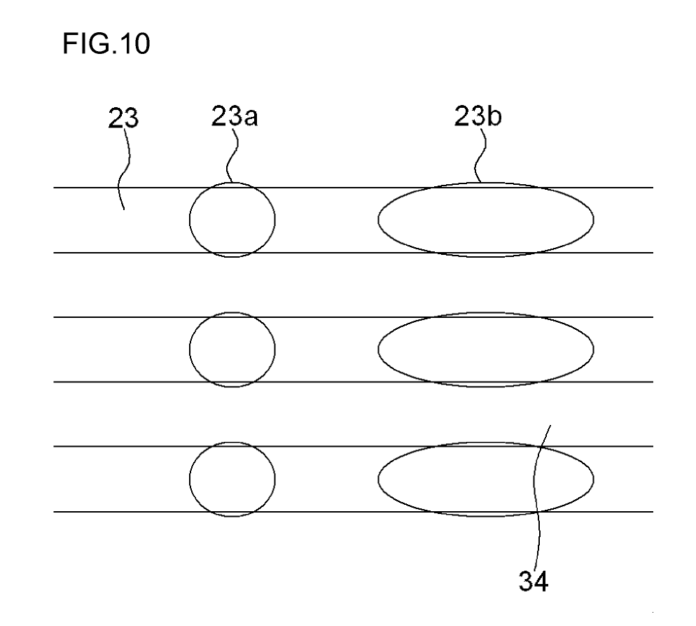

FIG. 10 is a schematic plan view illustrating a semiconductor substrate of a non-volatile semiconductor memory device according to the second exemplary embodiment of the present invention. In this exemplary embodiment, first impurity diffusion regions 23a that are adjacent to each other in the vertical direction in FIG. 10 are electrically interconnected by the diffusion-region wiring 35. Accordingly, the diffusion layers 23 extending linearly in the horizontal direction in FIG. 10 are isolated by the vertically adjacent diffusion layers and element isolation regions 34. That is, the element isolation regions 34 are formed in the shape of lines extending in the horizontal direction in FIG. 10.

In a manner similar to the first exemplary embodiment, the length L3 of the memory gate 26 is less than that of the control gate 28. Further, it is preferred that the top surface of the memory gate 26 not be curved or inclined with respect to a semiconductor substrate, and it is particularly preferred that the top surface be parallel to the semiconductor substrate 22.

The height H3 of the memory gate 26 (particularly the height of the side surface opposing the control gate 28 and diffusion-region wiring 35) is different from the height H5 of the control gate 28 and diffusion-region wiring 35 (particularly the height of the side surface opposing the memory gate 26). For example, the height H3 of the uppermost end of the side surface of memory gate 26 opposing the control gate 28 and diffusion-region wiring 35 is lower than the height H4 of the uppermost end of the side surfaces of the control gate 28 and diffusion-region wiring 35 opposing the memory gate 26. It should be noted that although the heights of the control gate 28 and diffusion-region wiring 35 are made the same in FIG. 9, it does not matter if they are the same.

Silicide films 26a, 28a 35a are formed on the top surfaces of the memory gate 26, control gate 28 and diffusion-region wiring 35. In order to prevent a short circuit between the memory gate 26 and control gate 28, a lower inter-gate insulating film 30 and an upper inter-gate insulating film 31 are formed between the memory gate 26 and control gate 28 in a manner similar to the first exemplary embodiment. Furthermore, in order to prevent a short circuit between the memory gate 26 and diffusion-region wiring 35 in this exemplary embodiment, a lower inter-gate wiring insulating film 40 and an upper inter-gate wiring insulating film 41 are formed between the memory gate 26 and diffusion-region wiring 35. The composition of a charge storage film 25 and the composition of the lower inter-gate wiring insulating film 40 can be made different from each other, and the composition of the lower inter-gate wiring insulating film 40 and the composition of the upper inter-gate wiring insulating film 41 can be made different from each other. For example, ONO film can be used as the charge storage film 25, ON film can be used as the lower inter-gate wiring insulating film 40, and silicon oxide film can be used as the upper inter-gate wiring insulating film 41. Further, the composition of the lower inter-gate insulating film 30 and that of the lower inter-gate wiring insulating film 40 can be made the same, and the composition of the upper inter-gate insulating film 31 and that of the upper inter-gate wiring insulating film 41 can be made the same.

Modes of the second exemplary embodiment other than those mentioned above are similar to those of the first exemplary embodiment and need not be described again.

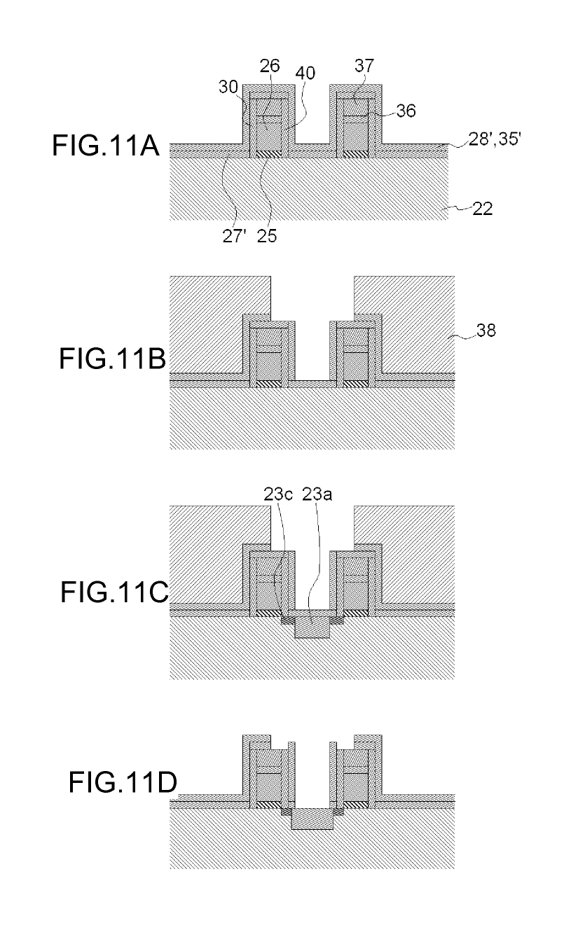

Next, a method of manufacturing the non-volatile semiconductor memory device according to the second exemplary embodiment of the present invention will be described. FIGS. 11A to 13E are schematic process views for describing a method of manufacturing the non-volatile semiconductor memory device according to the second exemplary embodiment of the present invention shown in FIGS. 8 and 9. FIGS. 11A to 13E are schematic sectional views of a portion corresponding to the sectional portion of FIG. 8 taken along line IX-IX.

First, a laminate having the charge storage film (e.g., ONO film) 25, memory gate e.g., polysilicon) 26, a third protective insulating film (e.g., silicon oxide film) 36 and a lift-up film (silicon nitride film) 37 is formed on the semiconductor substrate 22 in a manner similar to that shown in FIGS. 4A to 5B according to the first exemplary embodiment. The lower inter-gate insulating film (e.g., ON film) 30 and upper inter-gate wiring insulating film (e.g., ON film) 41 are formed on both sides of the laminate. A gate insulating film precursor layer 27′ (e.g., silicon oxide film) 27′ that will serve as the base of a gate insulating film 27 is formed on the semiconductor substrate 22 and on the laminate. First control gate precursor layers (e.g., polysilicon layers) 28′, 35′ that will serve as bases of part of the control gate 28 and diffusion-region wiring 35 is formed are formed over the entire surface of the uppermost layer [FIG. 11A]. This exemplary embodiment differs from the first exemplary embodiment in that two of the laminates are formed on the semiconductor substrate 22 and the two laminates are spaced apart by the length of the diffusion-region wiring 35. Further, the first control gate precursor layers (e.g., polysilicon layers) 28′, 35′ are layers formed in order to protect the gate insulating film precursor layer 27′ at subsequent steps; formation can be omitted if the gate insulating film precursor layer 27′ will not sustain damage.

Next, a resist 38 is formed so as to span the region for forming the diffusion-region wiring 35 and leave open the space between the top surfaces of the laminates, and the first control gate precursor layers 28′, 35′ are etched back [FIG. 11B]. Next, an impurity (e.g., arsenic) is injected into the semiconductor substrate 22 to thereby form the first impurity diffusion region 23a (inclusive of LDD 23c) [FIG. 11C]. Next, after the resist 38 is removed, the gate insulating film precursor layer 27′ on the first impurity diffusion region 23a is removed [FIG. 11D].

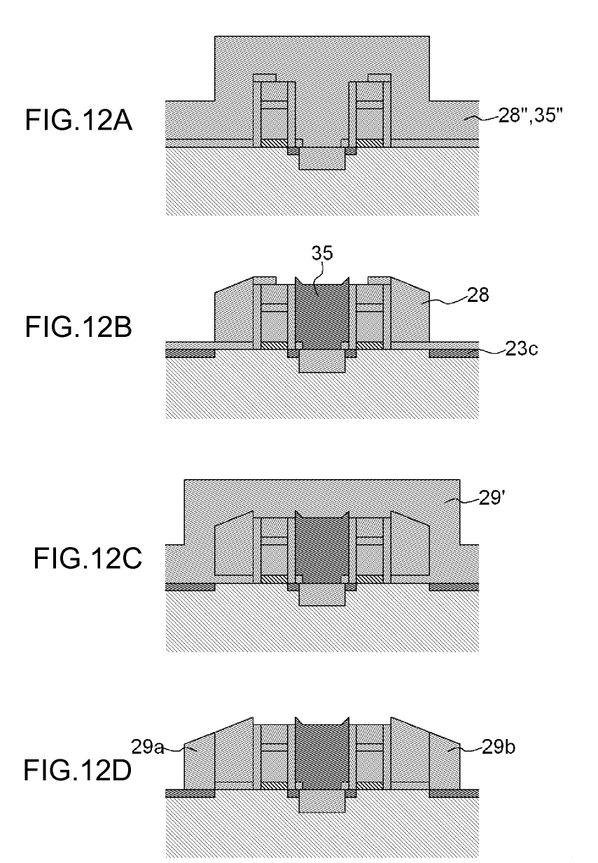

Next, after second control gate precursor layers (e.g., polysilicon layers) 28″, 35″ that will serve as the bases of the control gate 28 and diffusion-region wiring 35 are formed over the entire surface [FIG. 12A], they are etched back to form the control gate 28 and diffusion-region wiring 35. Next, an impurity is injected into the second impurity diffusion region 23b to form the LDD 23c [FIG. 12B]. Next, after first and second protective insulating film precursor layers (e.g., silicon oxide film) 29′ that will serve as the base of first and second protecting insulating films 29a, 29b are formed [FIG. 12C], they are etched back to form the first and second protecting insulating films 29a, 29b [FIG. 12D].

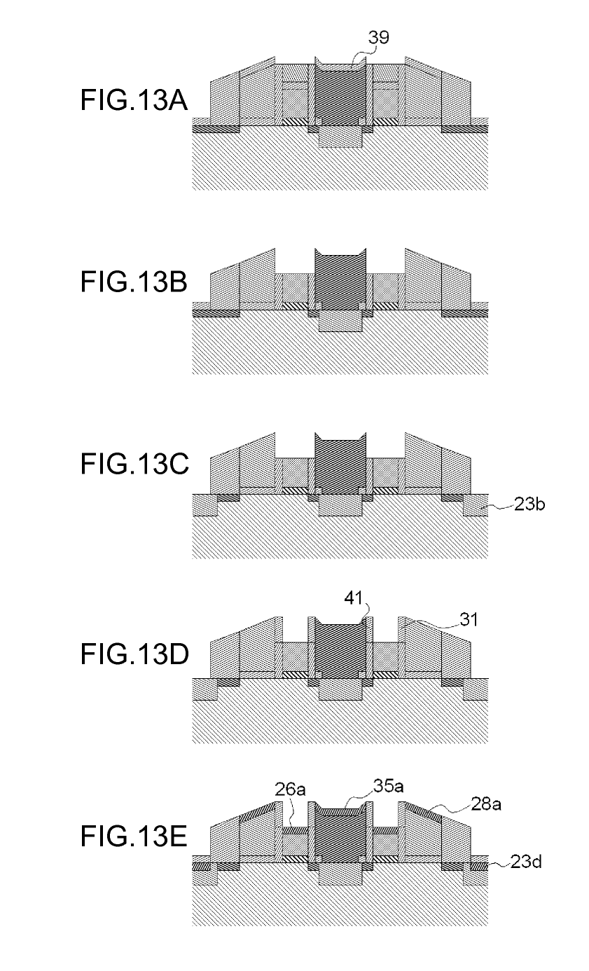

Next, in a case where the lift-up film 37 is a silicon nitride film and the third protective insulating film 36 is a silicon oxide film, by way of example, the entirety is oxidized under conditions in which the lift-up film 37 is not oxidized, thereby forming a fourth protective insulating film (e.g., a silicon oxide film) 39 [FIG. 13A]. Next, the lift-up film 37 is removed using the fourth protective insulating film 39 as a mask, then the fourth protective insulating film 39 is removed [FIG. 13B]. Next, an impurity (e.g., N⁺) is injected to thereby form the second impurity diffusion region 23b [FIG. 13C]. Next, after an upper insulating precursor layer (e.g., silicon oxide film) that will serve as the base of the upper inter-gate insulating film 31 and upper inter-gate wiring insulating film 41 is formed over the entire surface, the upper inter-gate insulating film 31 and upper inter-gate wiring insulating film 41 are formed by etch-back [FIG. 13D]. Next, the memory gate 26, control gate 28, impurity diffusion regions 23a, 23b and diffusion-region wiring 35 are silicided to thereby form the silicide films 26a, 28a, 23d, 35a [FIG. 13E]. Next, the interlayer insulating film 33, contact 32 and wiring, etc., are formed in the order mentioned, thereby manufacturing the non-volatile semiconductor memory device 21.

In this exemplary embodiment, effects similar to those of the first exemplary embodiment can be obtained.

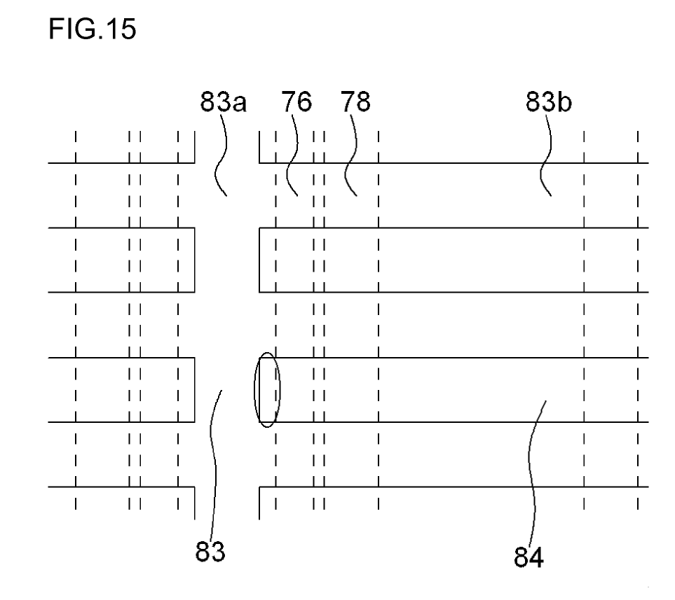

Further, in accordance with the non-volatile semiconductor memory device of this exemplary embodiment, the necessary area can be reduced by forming the diffusion-region wiring 35. FIG. 15 is a schematic plan view illustrating a semiconductor substrate of a non-volatile semiconductor memory device in which diffusion-region wiring is not formed. The positions of a memory gate 76 and control gate 78 are indicated by dashed lines in FIG. 15. In a case where diffusion-region wiring is not formed on the semiconductor substrate, it is required that an element isolation region 84 be formed in such a manner that a line-shaped diffusion layer 83 extending in the horizontal direction in FIG. 15 is partially connected with a diffusion layer extending in the vertical direction. That is, the element isolation region 84 is formed in such a manner that the diffusion layer will exist between the memory gates 76. Since lithographic deviation or corner-shaped rounding at the end portion of the element isolation region 84 (the region facing a first impurity diffusion region 83a) affects the characteristic of the memory cell, it is required that a prescribed distance (see the elliptical symbol in FIG. 15) be assured between the memory gate 76 and end portion of the element isolation region 84 at this time. In accordance with this exemplary embodiment, however, as illustrated in FIG. 10, the diffusion-region wiring 35 is formed and the element isolation region 34 is formed in linear fashion (a diffusion layer is not formed between the adjacent memory gates 26), as a result of which it is unnecessary to provide distance between the memory gate and the end portion of the element isolation region. This means that the size of the memory cell can be reduced correspondingly.

Further, in a case where a contact is connected to an impurity diffusion region, it is required that a prescribed spacing be provided between the contact connected to the diffusion layer and the memory gate. In accordance with the present invention, however, the diffusion-region wiring 35 is formed. As a result, it is no longer necessary to form a contact connected to the diffusion layer and no longer necessary to assure this spacing. Furthermore, electrical characteristics can be enhanced by siliciding the top surfaces of the memory gate, control gate and diffusion region wiring.

In accordance with the method of manufacture according to this exemplary embodiment, the height of the memory gate 26 and the height of the diffusion-region wiring 35 are changed and the upper and lower inter-gate insulating films 40, 41 are disposed between these two members, thereby making it possible to prevent a short circuit between the memory gate 26 (inclusive of the silicide film 26a) and the diffusion-region wiring 35 (inclusive of the silicide film 35a).

Furthermore, in accordance with the method of manufacture according to this exemplary embodiment, degradation of the gate insulating film 27 can be suppressed by forming the first control gate precursor layers (e.g., polysilicon layers) 28′, 35′ after the gate insulating film precursor layer 27′ is formed. If the gate insulating film precursor layer 27′ is formed after an impurity is injected into the substrate, the impurity that has been injected into the substrate will fly out of the substrate and penetrate the gate insulating film precursor layer 27′, as a result of which the gate insulating film deteriorates. This means that it is necessary to inject the impurity into the substrate after the gate insulating film precursor layer 27′ is formed. However, if the resist 38 is formed directly on the gate insulating film precursor layer 27′ in order to inject the impurity, this also will degrade the gate insulating film. Accordingly, in this exemplary embodiment, the resist 38 is formed and the impurity injected after the first control gate precursor layers 28′, 35′ are formed, thereby making it possible to diminish degradation of the gate insulating film ascribable to the protrusion of the impurity and the formation of the resist. This exemplary embodiment is suited to logic transistors that require a high reliability, e.g., a flash memory co-resident with a microcomputer. If a high reliability is not required, then the resist 38 may be formed and the impurity injected after forming the first control gate precursor layers 28′, 35′ following the formation of the gate insulating film precursor layer 27′. In such case a control gate precursor layer that will serve as the base of the control gate 28 and diffusion-region wiring 35 can be formed by a single treatment.

The non-volatile semiconductor memory device and method of manufacturing the device according to the present invention have been described based upon the foregoing exemplary embodiments. However, it goes without saying that the present invention is not limited to these exemplary embodiments and the exemplary embodiments can be modified, altered and improved in various ways within the scope of the claims of the present invention and based upon the fundamental technical idea of the present invention. Further, the various disclosed elements can be combined, substituted or selected in various ways within the scope of the claims of the present invention.

Other objects, features and advantages of the present invention will be apparent from the full disclosure of the present invention inclusive of the scope of the claims. It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A non-volatile semiconductor memory device comprising:
a semiconductor substrate;
a charge storage film disposed on said semiconductor substrate;
a first gate electrode disposed on said charge storage film;
a gate insulating film disposed on said semiconductor substrate;
a second gate electrode disposed on said gate insulating film; and
an inter-gate insulating film disposed between said first gate electrode and said second gate electrode;
wherein length of said first gate electrode is smaller than that of said second gate electrode; and
a top surface of said first gate electrode is neither curved nor inclined with respect to said semiconductor substrate.

2. The device according to claim 1, wherein height of an uppermost end of said first gate electrode with respect to the surface of said semiconductor substrate and height of an uppermost end of said second gate electrode with respect to the surface of said semiconductor substrate are different.

3. The device according to claim 2, wherein the height of an uppermost end of said first gate electrode with respect to the surface of said semiconductor substrate is lower than that of an uppermost end of said second gate electrode with respect to the surface of said semiconductor substrate.

4. The device according to claim 1, wherein said first gate electrode and said second gate electrode each have polysilicon and each has a silicide film on the top surface thereof; and
said inter-gate insulating film is disposed on a side surface facing whichever of said first and second gate electrodes is the higher gate electrode, which opposes the other gate electrode that is the lower gate electrode, said inter-gate insulating film extending between the top surface of the one gate electrode and the top surface of the other gate electrode.

5. The device according to claim 4, wherein said inter-gate insulating film has a lower inter-gate insulating film extending from the surface of said semiconductor substrate to the top surface of the one gate electrode, and an upper inter-gate insulating film extending from the top surface of the one gate electrode to the top surface of the other gate electrode.

6. The device according to claim 5, wherein said gate insulating film and said lower inter-gate insulating film have compositions that differ from each other.

7. The device according to claim 5, wherein said charge storage film and said lower inter-gate insulating film have compositions that differ from each other.

8. The device according to claim 1, further comprising:
diffusion-region wiring disposed on a first impurity diffusion region of said semiconductor substrate; and
an inter-gate wiring insulating film disposed between said diffusion-region wiring and said first gate electrode;
wherein said charge storage film and said first gate electrode are disposed on both sides of said diffusion-region wiring;
said gate insulating film and said second gate electrode are disposed on the side of each charge storage film and each first gate electrode that is opposite said diffusion-region wiring; and
a second impurity diffusion region of said semiconductor substrate is disposed on the side of each gate insulating film and each second gate electrode that is opposite said charge storage film and aid first gate electrode.

9. The device according to claim 8, wherein the height of the uppermost end of the first gate electrode with respect to the surface of said semiconductor substrate and that of the uppermost end of said diffusion-region wiring with respect to the surface of said semiconductor substrate are different.

10. The device according to claim 9, wherein the height of the uppermost end of said first gate electrode with respect to the surface of said semiconductor substrate is lower than that of the uppermost end of said diffusion-region wiring with respect to the surface of said semiconductor substrate.

11. The device according to claim 9, wherein said diffusion-region wiring has polysilicon and comprises a silicide film on a top surface thereof; and
said inter-gate wiring insulating film is disposed on a side surface facing whichever of said first gate electrode and diffusion-region wiring is the higher one, which opposes the one that is the lower, said inter-gate wiring insulating film extending between the top surface of the one and the top surface of the other.

12. The device according to claim 11, wherein said inter-gate wiring insulating film has a lower inter-gate wiring insulating film extending from the surface of said semiconductor substrate to the top surface of the one, and an upper inter-gate wiring insulating film extending from the top surface of the one to the top surface of the other.

13. The device according to claim 11, wherein said charge storage film and said lower inter-gate insulating film have compositions that differ from each other.

14. The device according to claim 1, wherein the top surface of said first gate electrode is a planar shape parallel to the surface of said semiconductor substrate.

15. The device according to claim 1, wherein said first gate electrode is formed using lithography.

16. The device according to claim 1, wherein the top surface of said second gate electrode is a curved surface or is inclined with respect to the surface of said semiconductor substrate.

17. The device according to claim 1, wherein said second gate electrode is formed as a sidewall utilizing at least said first gate electrode.

18. The device according to claim 1, wherein said first gate electrode is a memory gate and said second gate electrode is a control gate.

19. A method of manufacturing a non-volatile semiconductor memory device, comprising:
forming a first gate electrode, which has been formed utilizing lithography, on a semiconductor substrate; and
forming a second gate electrode, which has a length greater than that of the first gate electrode, as a sidewall of at least the first gate electrode.

20. The method according to claim 19, further comprising:
forming a charge storage film on the semiconductor substrate;
forming the first electrode on the charge storage film;
forming a laminate, which has the charge storage film and the first gate electrode, into a prescribed shape using lithography;
forming an inter-gate insulating film on at least one side surface of the laminate;
forming a gate insulating film on the semiconductor substrate; and
forming the second gate electrode on the gate insulating film as a sidewall of the laminate via the inter-gate insulating film.
